(19) United States
(12) Patent Application Publication
(10) Pub. No.: US 2025/0306070 A1
(43) Pub. Date: Oct. 2, 2025

(54) APPARATUS AND METHOD FOR MEASURING ELECTRICAL CONDUCTIVITY OF SEMICONDUCTOR SUBSTRATE

(71) Applicant: Samsung Electronics Co., Ltd., Suwon-si (KR)

(72) Inventors: Kwang-Eun Kim, Suwon-si (KR); SEO YOUNG PARK, Suwon-si (KR); JEONGHO AHN, Suwon-si (KR); SUNGEUN LEE, Suwon-si (KR)

(21) Appl. No.: 18/906,030

(22) Filed: Oct. 3, 2024

(30) Foreign Application Priority Data
Mar. 28, 2024 (KR) 10-2024-0042691

(51) Int. Cl. G01R 27/02

(52) U.S. Cl. CPC G01R 27/02

(57) ABSTRACT

An electrical conductivity measuring method of a semiconductor substrate according to an embodiment includes: producing a scanning electron microscope (SEM) image of a standard sample using a scanning electron microscope; producing a SEM image of a surface of the semiconductor substrate with the scanning electron microscope; calculating a degree of image distortion by comparing the SEM image of the standard sample and the SEM image of the semiconductor substrate surface; and evaluating the electrical conductivity of the semiconductor substrate based on the degree of image distortion.

### CROSS-REFERENCE TO RELATED APPLICATION

This application claims priority to and the benefit of Korean Patent Application No. 10-2024-0042691 filed in the Korean Intellectual Property Office on Mar. 28, 2024, the entire contents of which are incorporated herein by reference.

### BACKGROUND OF THE INVENTION

### (a) Field of the Invention

The present disclosure relates to an electrical conductivity measurement device for a semiconductor substrate and an electrical conductivity measurement method of a semiconductor substrate.

### (b) Description of the Related Art

In a semiconductor device manufacturing process, electrical conductivity is an important variable that determines the characteristics of the device. Since differences occur in material thickness, pattern width, and charge doping amount depending on a local position within a wafer, it is necessary to measure electrical conductivity within the local region.

Electrical conductivity can be measured using a contact probe in a separate pattern for electrical conductivity measurement within the wafer. However, since this method measures a separate region from a region in which the actual device operates, there is a difference from the electrical conductivity of the actual device, and there is a drawback of requiring a separate region for measurement patterns.

Therefore, a method to measure electrical conductivity in the region where the actual device within the wafer operates is required.

### SUMMARY OF THE INVENTION

One aspect of the embodiments provides an electrical conductivity measurement device and a measurement method of a semiconductor substrate that can detect the electrical conductivity of a local region by calculating an image shape distortion caused by an electrical potential difference during scanning electron microscope (SEM) measurement.

However, problems that embodiments of the present disclosure seek to solve are not limited to the above-mentioned problems and can be expanded in various ways within the range of technical ideas included in the present disclosure.

An electrical conductivity measurement device of a semiconductor substrate according to one aspect includes: a stage to place the semiconductor substrate; a scanning electron microscope configured to obtain a scanning electron microscope (SEM) image of a surface of a semiconductor substrate by scanning the surface of the semiconductor substrate with a focused electron beam; and a computer configured to measure the electrical conductivity of the semiconductor substrate by calculating a distortion value of the SEM image.

An electrical conductivity measuring method of a semiconductor substrate according to another aspect includes: producing a scanning electron microscope (SEM) image of a standard sample using a scanning electron microscope; producing a SEM image of a surface of the semiconductor substrate with the scanning electron microscope; calculating a degree of image distortion by comparing the SEM image of the standard sample and the SEM image of the semiconductor substrate surface; and evaluating the electrical conductivity of the semiconductor substrate based on the degree of image distortion.

According to the embodiments, the electrical conductivity of a local region can be detected by calculating shape distortion due to the difference in electrical potential occurring during SEM measurement/scanning/inspection.

Since the SEM measurement/scanning/inspection is performed each time the process progresses, there is no need for a separate measurement step to measure electrical conductivity. In addition, the electrical conductivity can be measured with a resolution of less than 1 micrometer, which is the SEM image measurement size.

### BRIEF DESCRIPTION OF THE DRAWINGS

FIG. 1 schematically illustrates an electrical conductivity measurement device of a semiconductor substrate according to an embodiment.

FIG. 2 is a relationship graph of electrical conductivity and an SEM image distortion value according to the magnitude of an applied voltage.

FIG. 3 is a schematic view provided for description of the principle of the electrical conductivity measurement method of a semiconductor substrate.

FIG. 4 is an SEM image that shows image distortion of the semiconductor substrate surface.

FIG. 5 schematically illustrates a semiconductor substrate for description of a method for measuring electrical conductivity of a semiconductor substrate according to an embodiment.

FIG. 6 is a graph that shows the difference in electrical potential between a scan region and a non-scan region caused by the difference in electrical conductivity of the semiconductor substrate and the degree of an electric field generated accordingly.

FIG. 7 is a flowchart that shows the electrical conductivity measurement method of the semiconductor substrate according to an embodiment.

FIG. 8 shows SEM images that respectively show image distortion at various positions of the semiconductor substrate surface.

FIG. 9 is a drawing schematically showing a hole to calculate image distortion values.

FIG. 10 compares SEM images of the standard sample and the actual measurement sample, and corners of the SEM images are enlarged.

FIG. 11 is a graph that shows bar widths between adjacent holes and diameters of individual holes measured from SEM images of the standard sample and the actual measurement sample.

FIG. 12 is a relationship graph of an electron beam energy with a secondary electron (SE) yield.

FIG. 13 and FIG. 14 schematically show electric field directions between a scan region and a non-scan region according to carrier types of the semiconductor substrate.

### DETAILED DESCRIPTION OF THE EMBODIMENTS

Hereinafter, with reference to the accompanying drawings, several embodiments of the present disclosure will be described in detail and thus a person of an ordinary skill can easily practice it in the technical field to which the present disclosure belongs. The present disclosure may be implemented in a number of different forms and is not limited to the embodiments described herein.

In order to clearly describe the present disclosure, parts not explained and having no relationship with explanation are omitted, and the same reference sign/numeral is used for identical or similar components throughout the specification.

In addition, since the size and thickness of each component shown in the drawing are arbitrarily indicated for better understanding and ease of description, the present disclosure is not necessarily limited to what is shown. In order to clearly express several layers and regions in the drawing, the thickness is enlarged. In addition, in drawings, the thicknesses of some layers and regions are exaggerated for better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In a semiconductor manufacturing process, high-quality semiconductor products can be produced, a production process can be improved, and defects can be prevented by inspecting semiconductor wafers using a scanning electron microscope (SEM).

Since a scanning electron microscope can check the pattern and structure of a fine nanometer unit with high resolution, it is possible to visually check (e.g., by SEM images) the surface of a semiconductor wafer with various fine patterns and structures. For example, when inspecting the surface of a semiconductor wafer, a scanning electron microscope can be used to identify and detect fine defects, failures, or areas with potential malfunction.

A scanning electron microscope is equipment that uses electrons to observe a surface of a sample with high resolution. The scanning electron microscope generates an electron beam (E-beam) and collides it with the sample surface. The electron beam that collides with the sample surface interacts with the atoms of the sample to generate backscattered electrons (BSE) and secondary electrons (SE). The electrons generated in this way are measured by a detector and converted into an image. In this case, the backscattering electrons (BSE) are related to the atom number and density of the sample, and the secondary electrons (SE) represent the shape and texture of the surface. The scanning electron microscope can use these signals to observe fine surface structures and defects at high resolution.

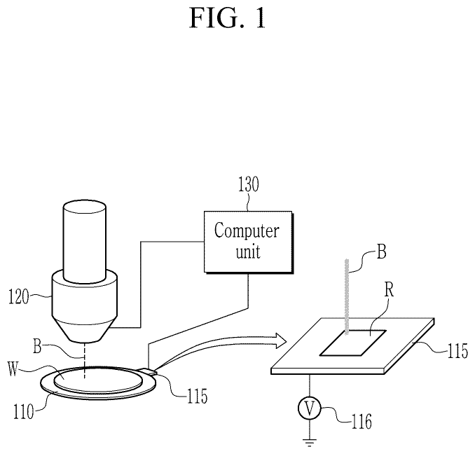

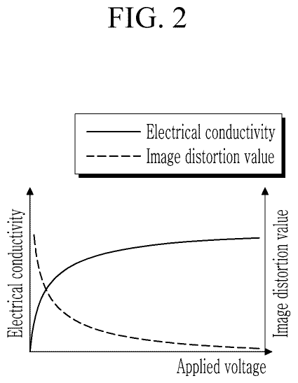

FIG. 1 schematically illustrates an electrical conductivity measurement device of a semiconductor substrate according to an embodiment, and FIG. 2 is a relationship graph of electrical conductivity and an SEM image distortion value according to the magnitude of an applied voltage.

Referring to FIG. 1, an electrical conductivity measurement device of a semiconductor substrate according to the present embodiment includes a stage 110, a scanning electron microscope 120 placed on the stage 110, and a computer unit 130 for image analysis. A semiconductor substrate W is placed on the stage 110, and the scanning electron microscope 120 emits an electron beam toward the semiconductor substrate W and scans the surface of the semiconductor substrate W to obtain a scanning electron microscope (SEM) image. The computer unit 130 may calculate a distortion value of an image of the semiconductor substrate W by analyzing the SEM image obtained from the scanning electron microscope 120. In addition, the computer unit 130 may derive the electrical conductivity of the surface of the semiconductor substrate W from the distortion value of the image. The semiconductor substrate W may be a silicon (Si) wafer. The computer unit 130 may be a computer. The computer may be a general purpose computer or may be dedicated hardware or firmware (e.g., an electronic or optical circuit, such as application-specific hardware, such as, for example, a digital signal processor (DSP) or a field-programmable gate array (FPGA)). A computer may be configured from several interconnected computers.

A standard sample chuck 115 may be provided on one edge of the stage 110 to prepare a standard sample R. A voltage application unit 116 that applies a voltage and controls the magnitude of the applied voltage may be connected to the standard sample chuck 115. The voltage application unit 116 may be a power source providing electric power (e.g., electric bias) to the standard sample chuck 115 and/or to the standard sample R. The standard sample R may be a silicon (Si)-based sample, e.g., a silicon substrate or a semiconductor substrate.

As shown in FIG. 2, the electrical conductivity of the standard sample R may change depending on the magnitude of the applied voltage, and the relationship information between the applied voltage and electrical conductivity is known in advance. While changing the applied voltage, the scanning electron microscope 120 scans the standard sample R by emitting the electron beam B to the standard sample R to calculate the image distortion value. Since the electrical conductivity according to the applied voltage of the standard sample R is known, image distortion value data according to the change in electrical conductivity can be tabulated (or graphed). The distortion value obtained when measuring the actual semiconductor substrate W mounted on the stage 110 can be converted to electrical conductivity based on the measurement information of the standard sample R. For example, when the image distortion value of the semiconductor substrate W is measured, a corresponding electrical conductivity value can be found in the graph of FIG. 2.

Hereinafter, a method for measuring the electrical conductivity of the semiconductor substrate will be described in more detail.

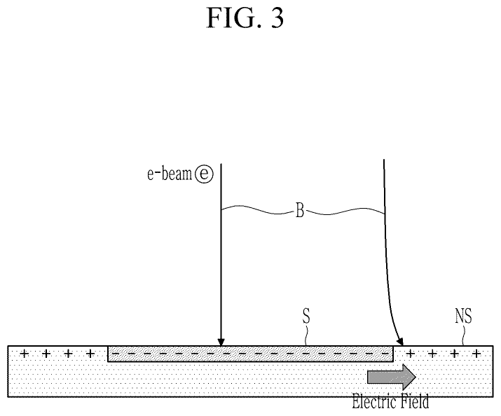

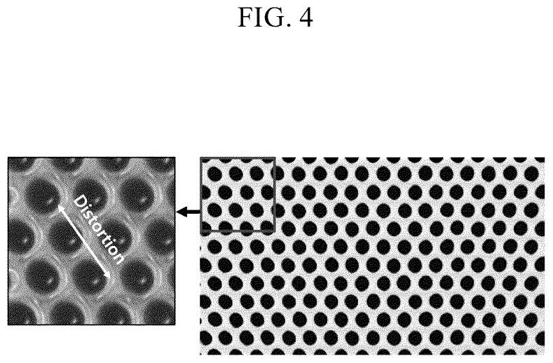

FIG. 3 is a schematic view provided for description of the principle of the electrical conductivity measurement method of a semiconductor substrate, and FIG. 4 is an SEM image that shows image distortion of the semiconductor substrate surface.

Referring to FIG. 3, when measuring using a scanning electron microscope by scanning the sample semiconductor substrate W using an electron beam B, differences in electrical potential may occur on the surface of the semiconductor substrate W. In addition, an electric field may be formed due to a potential difference ΔV between a scan region S and a non-scan region NS. The electron beam B is affected by the electric field formed in this way, causing bending of a path, which may cause distortion of the SEM image.

In order for a wafer formed of silicon (Si) to be used as a semiconductor substrate, processes may be repeated to form various materials/layers on the wafer surface and etching the various materials/layers according to designed circuit shape. As a basic step in the processes, an oxidation process is performed, where oxygen or vapor is sprayed on the wafer surface at high temperature (800° C. to 1,200° C.) to form a thin and uniform silicon oxide layer (SiO₂) on the wafer. The silicon oxide layer formed on the wafer may be accumulated to form a hole pattern, e.g., including one or more holes.

Referring to FIG. 4, it can be observed that distortion occurred in a corner direction in an edge portion (e.g., in an edge or in a portion of edge) of the image obtained from the scanning electron microscope. For example, each of holes in the edge of the image may have an ellipse shape, and the major axis of the ellipse shape of each hole may be parallel or substantially parallel with a line connecting the center of the corresponding hole and a corner of the image. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. The electrical potential difference ΔV between the scan region S and the non-scan region NS is proportional to a charge accumulation amount ΔQ, which is proportional to the reciprocal of the electrical conductivity σ of the semiconductor substrate (ΔV∝ΔQ∝1/σ). Therefore, the difference in relative electrical conductivity of the sample semiconductor substrate W can be inferred/determined by comparing the degree of distortion of the image.

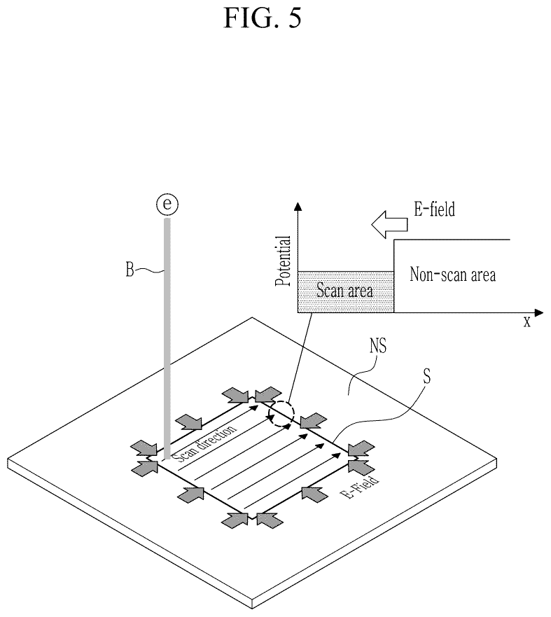

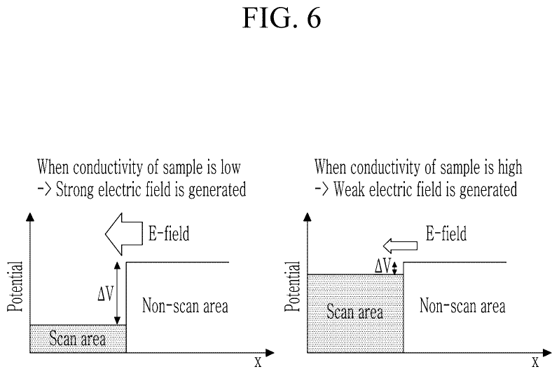

FIG. 5 schematically illustrates a semiconductor substrate for description of a method for measuring electrical conductivity of a semiconductor substrate according to an embodiment, and FIG. 6 is a graph that shows the difference in electrical potential between a scan region and a non-scan region caused by the difference in electrical conductivity of the semiconductor substrate and the degree of an electric field generated accordingly.

Referring to FIG. 5, when the scan region S is defined on the semiconductor substrate W, an electron beam B can be emitted to the scan region S by the scanning electron microscope 120 to scan the scan region S, and the SEM image can be obtained. In this case, as charge accumulates in the scan region S, a difference in electrical potential may occur between the scan region S and the surrounding non-scan region NS. Assuming that charge is uniformly accumulated in the scan region S, a difference in electrical potential occurs between the scan region S and the non-scan region NS, and therefore an electric field equal/corresponding to ΔV can be formed at the edge of the scan region S.

The intensity of the electric field varies depending on the accumulated amount of charge in the scan region S, and the accumulated amount of charge is closely related to the electrical conductivity of the semiconductor substrate W, which is the sample. For example, an accumulated charge amount Q may be expressed as Equation 1 below.

$$Q ∝ ( δ - 1 ) \cdot t / σ \qquad [ Equation 1 ]$$

Here, δ represents a secondary electron yield, σ represents the electrical conductivity of the sample, and t represents a scanning time of the sample or an emitting time of the electron beam to the sample.

Referring to Equation 1, when the electrical conductivity a of the sample is low, the accumulated charge Q increases, and accordingly, an electric field proportional to Q/ε may be induced between the scan region S and the non-scan region NS (where ε is the dielectric constant).

When the electric field generated between the scan region S and the non-scan region NS meets the electron beam B, electric force is applied between the electric field and the electron beam B. Due to the electric force, a path of the electron beam B bends toward a corner of the scan region S, causing distortion in the SEM image shape. The lower the electrical conductivity of the sample semiconductor substrate W, the stronger the electric force and the stronger electric field generated, and in this case, the path of the electron beam B is bent more and the degree of image distortion increases. Conversely, when the electrical conductivity of the sample semiconductor substrate W is high, a weak electric field is generated, and in this case, the path of the electron beam B is bent smaller and the degree of image distortion becomes smaller (refer to FIG. 6).

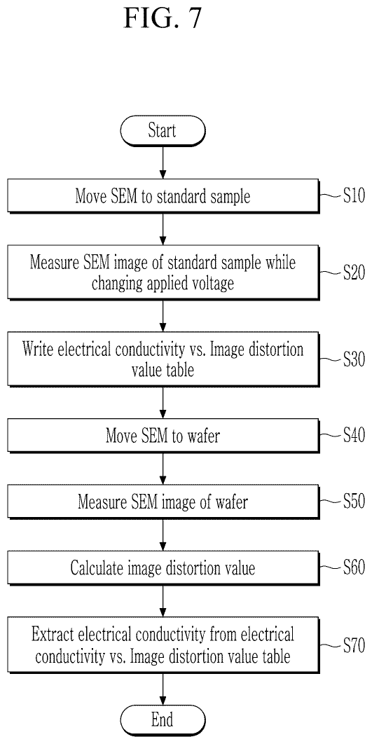

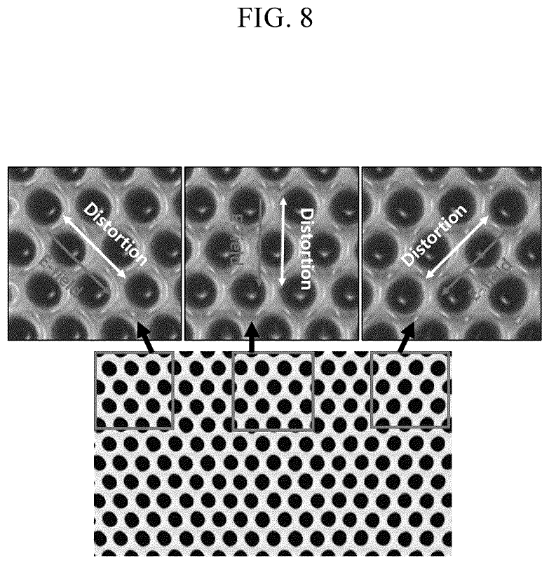

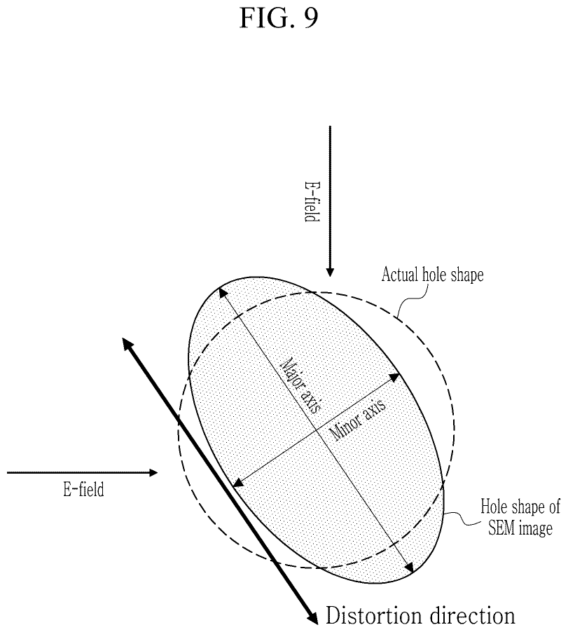

FIG. 7 is a flowchart that shows the electrical conductivity measurement method of the semiconductor substrate according to an embodiment, FIG. 8 shows SEM images that respectively show image distortion at various positions of the semiconductor substrate surface, and FIG. 9 schematically shows a hole for calculation of image distortion values.

The flowchart of FIG. 7 shows a method for measuring electrical conductivity of the semiconductor wafer W using the measurement device of FIG. 1. The electrical conductivity measurement method of the semiconductor substrate W according to the present embodiment includes the following steps.

First, the scanning electron microscope 120 is moved to the standard sample R (S10), and the SEM image is measured while changing a voltage applied to the standard sample R (S20). For example, when a wafer, e.g., the semiconductor substrate W, is loaded onto the stage 110, the scanning electron microscope 120 first moves to the standard sample R of which electrical conductivity is known. For example, the electrical resistance of silicon (Si) is around 1000 Ω·m at room temperature, and the resistance change value according to the degree of doping and the applied voltage is well known. Therefore, the standard sample R formed of or including silicon (Si) material of which electrical conductivity is well known may be mounted on the standard sample chuck 115 positioned next to the stage 110.

Next, image distortion numerical data according to changes in electrical conductivity are converted into a reference table (S30). Based on this, image distortion numerical data according to changes in electrical conductivity may be graphed (see FIG. 2). For example, the electrical conductivity varies depending on the voltage applied to the standard sample R, and when measuring the SEM image, the degree of image distortion also changes.

For example, referring to FIG. 8, after measuring the SEM image, the degree of image distortion may be calculated by calculating the ratio of the major axis to minor axis of a hole in the hole pattern at the image edge. For example, image distortion has a relationship as shown in Equation 2 below.

$$image distortion ∝ major axis / minor axis - 1 \qquad [ Equation 2 ]$$

Therefore, the ratio of the major axis to the minor axis varies depending on the degree of image distortion. In this way, the voltage applied to the standard sample can be converted to electrical conductivity, and ultimately, image distortion values according to electrical conductivity may be collected to form a database (e.g., the reference table).

Next, the scanning electron microscope 120 is moved to the semiconductor substrate W (S40) and the SEM image of the wafer surface of semiconductor substrate W is measured/obtained (S50).

Next, the image distortion value from the measured SEM image is calculated (S60).

As shown in FIG. 9, an electric field induced by accumulated charge may cause distortion in the hole shape at edges of the SEM image. The direction of distortion is parallel to the electric field direction. For example, a corner of the image is a region where the electric field is strongest and distorts the hole shapes the most. For this reason, the overall image distortion shape follows the barrel distortion shape.

The smaller the electrical conductivity, the stronger the electric field occurs at the border of the scan region S, increasing the image distortion value. Therefore, the distortion value of the SEM image measured from the wafer, which is a semiconductor substrate W, may be calculated by using Equation 3 below to determine how much distortion occurred in the pattern at the edge of the image compared to the pattern at a center of the image.

$$Image distortion value = {( major axis / minor axis - 1 )}_{edge hole} - {( major axis / minor axis - 1 )}_{center hole} \qquad [ Equation 3 ]$$

Here, (major axis/minor axis−1)_{center hole} is a value of calculation of the degree of distortion of a hole in the hole pattern in the image center portion (e.g., at the center and/or near the center of the image), and (major axis/minor axis−1)_{edge hole} is a value of calculation of the degree of distortion of a hole in the hole pattern in the image edge portion (e.g., in a portion of the edge of the image and/or near the edge of the image).

The distortion value calculation method described with reference to FIG. 8 and FIG. 9 presents a hole pattern in a form that makes it easy to calculate distortion when measuring SEM images. However, the method to calculate how much the shape of the pattern is distorted from an image with absence of image distortion as a reference may be selected variously, and the present inventive concept is not limited to the method described above.

Next, the electrical conductivity of the semiconductor substrate W is extracted from the reference table, e.g., an image distortion value data table according to the changes in the electrical conductivity (S70). For example, the electrical conductivity of the wafer may be inferred/determined by comparing the image distortion value measured from the wafer, e.g., a semiconductor substrate W, with the image distortion value database according to changes in the electrical conductivity.

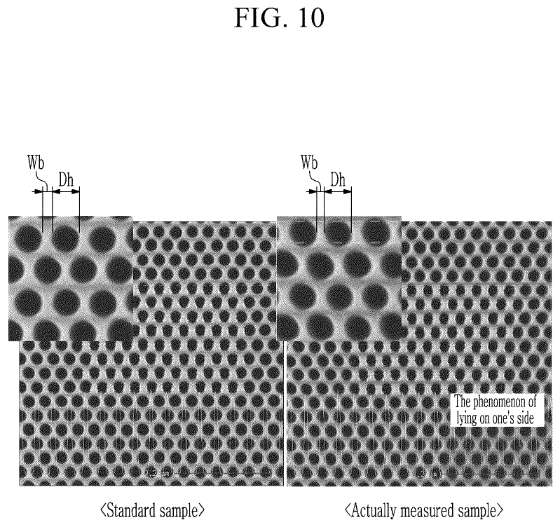

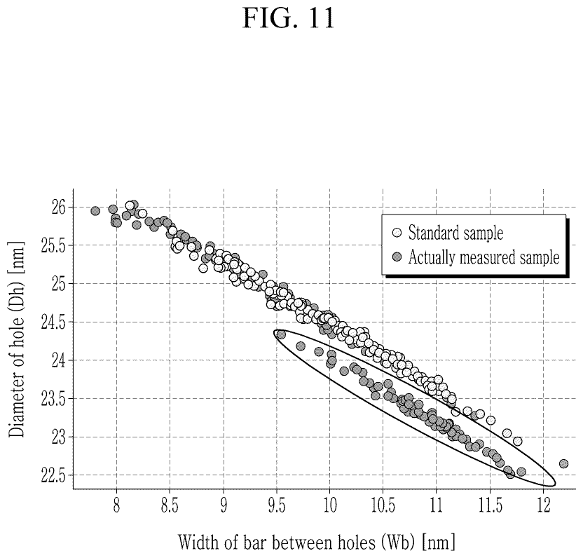

FIG. 10 compares SEM images of the standard sample and the actual measurement sample, and corners of the SEM images are enlarged. The image on the left is the SEM image of the standard sample, and the image on the right is the SEM image of the actual measurement sample. FIG. 11 is a graph that shows bar widths Wb between adjacent holes and diameters Dh of individual holes measured from SEM images of the standard sample and the actual measurement sample. For example, each of the bar widths Wb is a distance between two neighboring holes.

As shown in FIG. 10, the widths Wb of the bars between the holes and the diameters Dh of the holes in the standard sample are measured by measuring the SEM image, and the bar widths Wb and the hole diameters Dh of the actual measurement sample are measured under the same SEM measurement conditions as the ones of the standard sample and the bar widths Wb and the hole diameters Dh of the standard sample and the actual measurement sample are displayed in graph in FIG. 11. In the graph in FIG. 11, the light gray dots are values measured from the standard sample, and the dark gray dots are values measured from the actual measurement sample. For example, each of the SEM images may be a flat surface image taken from a point on a perpendicular line to the flat surface and passing through a center area of the flat surface. In the present disclosure, each of SEM measurement and measuring SEM images may be a process of obtaining/producing a SEM image by emitting an electron beam to a target sample.

Comparing the bar widths Wb and hole diameters Dh of the standard sample and the actual measurement sample with reference to the graph in FIG. 11, it can be observed that the hole diameters measured from the actual measurement sample are reduced by approximately 0.7 nm compared to the hole diameters measured from the standard sample. Therefore, it can be observed that the electrical conductivity of the actual measured sample is relatively low compared to the electrical conductivity of the standard sample. For example, when image distortion occurs due to low electrical conductivity of the actual measured sample, the diameter of the holes appearing in the SEM image may differ compared to the diameter of the holes in the standard sample. Depending on the conditions of the actual measurement sample, the measured value of the diameter may be larger or smaller. In FIG. 11, when the diameter of the holes shown in the SEM image is smaller than the diameter of the standard sample, the electrical conductivity of the sample may be low.

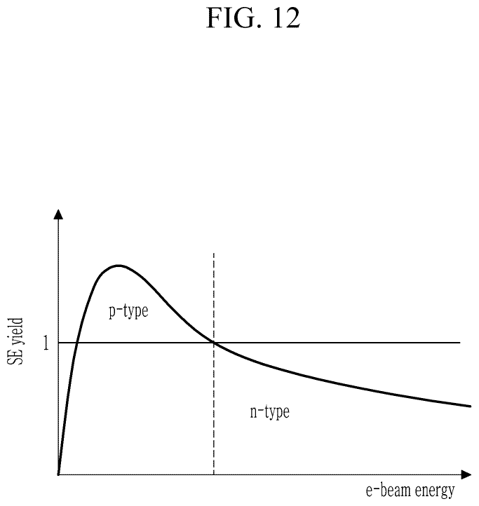

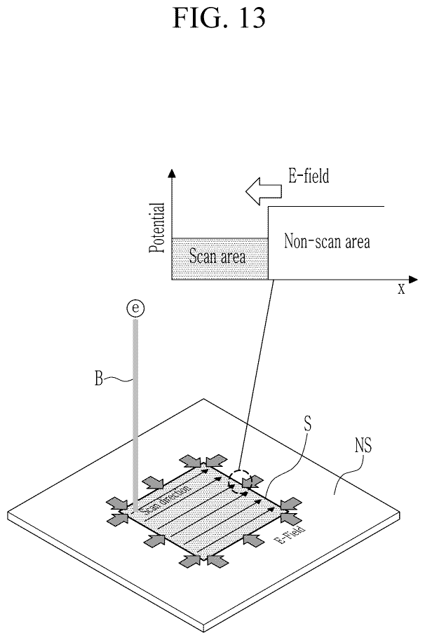

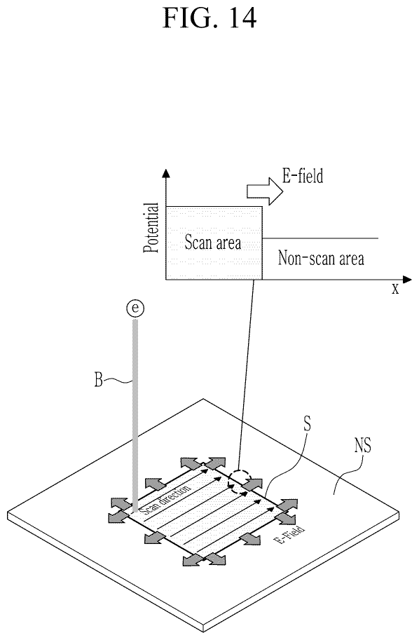

FIG. 12 is a relationship graph of an electron beam energy with a secondary electron (SE) yield, and FIG. 13 and FIG. 14 schematically show electric field directions between a scan region and a non-scan region according to carrier types of the semiconductor substrate.

Referring to FIG. 12, as the intensity of the electron beam energy changes, there are regions/domains where the secondary electron yield is greater than 1 and regions/domains where the secondary electron yield is less than 1. A generation amount of secondary electrons may be controlled by electron beam energy. In regions/domains where the secondary electron yield is greater than 1, more electrons are emitted from the sample than the number of incident electrons, resulting in a p-type doping effect. In addition, in regions/domains where the secondary electron yield is less than 1, the number of incident electrons is greater than the number of emitted electrons, resulting in an n-type doping effect.

For samples doped with p-type, when a low energy electron beam is emitted to scan the samples, there will be less image distortion, and when a high energy electron beam is emitted to scan the samples, there will be a lot of image distortion. Conversely, for n-type doped samples, when a low energy electron beam is emitted to scan the samples, image distortion is high, and when a high energy electron beam is emitted to scan the samples, image distortion is reduced. Therefore, when a low-energy electron beam is emitted to scan a sample of an unknown type and there is little or no image distortion, or when a high-energy electron beam is emitted to scan a sample, and there is significant image distortion, it can be known/decided that the sample is p-type doped (e.g., doped with p-type dopant).

On the contrary, when a low-energy electron beam is emitted to scan a sample of an unknown type and there is significant image distortion, or when a high-energy electron beam is emitted to scan a sample, and there is little or no image distortion, it can be known/decided that the sample is n-type doped (e.g., doped with n-type dopant).

In this way, it is possible to confirm/decide the carrier type of the sample by comparing the intensity of the applied electron beam energy and the image distortion result. In addition, electrical conductivity can be measured by classifying the sample by carrier type while changing the electron beam energy to acquire an SEM image and calculating the image distortion value from the SEM image.

FIG. 13 shows a state in which an electric field is formed due to the difference in electrical potential between the scan region S and the non-scan region NS when an electron beam is emitted to scan the n-type semiconductor substrate W. Since the electrical potential in the non-scan region NS is higher, an electric field directed from the non-scan region NS toward the scan region S may be formed.

FIG. 14 shows a state in which an electric field is formed due to the difference in electrical potential between the scan region S and the non-scan region NS when an electron beam is emitted to scan the p-type semiconductor substrate W. Since the electrical potential in the scan region S is higher, an electric field directed from the scan region S toward the non-scan region NS may be formed.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Although embodiments have been described in detail above, the scope of the present invention is not limited thereto, and various modifications by a person of ordinary skill in the art using the basic concept will be possible, and the scope of the present invention is defined by the following claims.

What is claimed is:

1. An electrical conductivity measurement device of a semiconductor substrate comprising:
a stage to place the semiconductor substrate is placed;
a scanning electron microscope configured to obtain a scanning electron microscope (SEM) image of a surface of a semiconductor substrate by scanning a surface of the semiconductor substrate with a focused electron beam; and
a computer configured to measure the electrical conductivity of the semiconductor substrate by calculating a distortion value of the SEM image.

2. The electrical conductivity measurement device of the semiconductor substrate of claim 1, further comprising
a standard sample chuck placed on one edge of the stage and configured such that a standard sample is loaded on the standard sample chuck.

3. The electrical conductivity measurement device of the semiconductor substrate of claim 2, wherein:
the computer is configured to calculate the electrical conductivity of the semiconductor substrate mounted on the stage based on measurement information of the standard sample obtained using the scanning electron microscope.

4. The electrical conductivity measurement device of the semiconductor substrate of claim 2, further comprising
a power source configured such that the power source applies voltage to the standard sample chuck while controlling the magnitude of the voltage applied to the standard sample chuck.

5. The electrical conductivity measurement device of the semiconductor substrate of claim 4, wherein:
the computer is configured to tabulate image distortion value data according to a change in electrical conductivity of the standard sample, calculate a distortion value of the SEM image of the semiconductor substrate, and convert the distortion value of the SEM image of the semiconductor substrate into electrical conductivity based on table data of the standard sample.

6. An electrical conductivity measuring method of a semiconductor substrate, comprising:
producing a scanning electron microscope (SEM) image of a standard sample using a scanning electron microscope;
producing a SEM image of a surface of the semiconductor substrate with the scanning electron microscope;
calculating a degree of image distortion by comparing the produced SEM image of the standard sample and the SEM image of the semiconductor substrate surface; and
evaluating the electrical conductivity of the semiconductor substrate based on the degree of image distortion.

7. The electrical conductivity measuring method of the semiconductor substrate of claim 6, further comprising
producing the SEM image while changing applied voltages to the standard sample and converting image distortion value data according to the change in the electrical conductivity of the standard sample into a reference table.

8. The electrical conductivity measuring method of the semiconductor substrate of claim 7, wherein:
the calculating the image distortion degree of the semiconductor substrate surface comprises calculating an image distortion value from the SEM image of the semiconductor substrate surface,
the evaluating the electrical conductivity of the semiconductor substrate comprises comparing the calculated image distortion values to the reference table to extract the electrical conductivity of the semiconductor substrate.

9. The electrical conductivity measuring method of the semiconductor substrate of claim 8, wherein:
the semiconductor substrate has a hole pattern on the surface.

10. The electrical conductivity measuring method of the semiconductor substrate of claim 9, wherein:
the calculating the image distortion value of the semiconductor substrate surface comprises
when the longest diameter of each modified individual hole of the hole pattern is a major axis and the shortest diameter is a minor axis, calculating a ratio of the major axis to the minor axis.

11. The electrical conductivity measuring method of the semiconductor substrate of claim 9, wherein:
the calculating the image distortion value of the semiconductor substrate surface comprises calculating a degree of distortion by comparing patterns in a center portion and patterns in an edge portion of the SEM image of the semiconductor substrate surface where the hole pattern is formed.

12. The electrical conductivity measuring method of the semiconductor substrate of claim 9, wherein:
when the longest diameter of each deformed individual hole of the hole pattern is a major axis and the shortest diameter is a minor axis, the image distortion value satisfies the following equation:
$$image distortion value = {( major axis / minor axis - 1 )}_{edge hole} - {( major axis / minor axis - 1 )}_{center hole}$$
here, (major axis/minor axis−1)_{center hole} is a value of calculation of a distortion degree of a hole in the hole pattern in the image center portion, and (major axis/minor axis-1)_{edge hole} is a value of calculation of a distortion degree of a hole in the hole pattern in the image edge portion.

13. The electrical conductivity measuring method of the semiconductor substrate of claim 6, wherein:
the evaluating the electrical conductivity of the semiconductor substrate comprises comparing a width of bars disposed between holes and a diameter of the holes measured in the standard sample with a width of bars disposed between holes and a diameter of the holes measured in the semiconductor substrate.

14. The electrical conductivity measuring method of the semiconductor substrate of claim 6, further comprising:
measuring intensity of electron beam energy emitted from the scanning electron microscope;
comparing a degree of image distortion with the intensity of the electron beam energy to infer a carrier type of the semiconductor substrate; and
measuring the electrical conductivity of the semiconductor substrate for each inferred carrier type.
